(19) United States
(12) Patent Application Publication
(10) Pub. No.: US 2023/0330658 A1
(43) Pub. Date: Oct. 19, 2023

(54) CALCITE COATED MICROFLUIDIC CELL AND METHODS THEREOF

(71) Applicant: SAUDI ARABIAN OIL COMPANY, Dhahran (SA)

(72) Inventors: Dong Kyu Cha, Dhahran (SA); Mohammed Badri Al-Otaibi, Dhahran (SA); Subhash C. Ayirala, Dhahran (SA); Ahmed Gmira, Al-Khobar (SA); Ali Abdallah Al-Yousef, Dhahran (SA)

(73) Assignee: SAUDI ARABIAN OIL COMPANY, Dhahran (SA)

(21) Appl. No.: 17/722,865

(22) Filed: Apr. 18, 2022

(51) Int. Cl. B01L 3/00; B33Y 10/00; B33Y 80/00; C23C 16/30

(52) U.S. Cl. CPC B01L 3/502707; B33Y 10/00; B33Y 80/00; C23C 16/30; B01L 2400/088; B29C 64/118

(57) ABSTRACT

A method includes 3d printing a polymer substrate having microfluidic channels and depositing calcite onto the polymer substrate then using atomic layer deposition to form a calcite microfluidic device. A device made from the method includes a 3d printed polymer substrate having microfluidic channels. The 3d printed polymer substrate has a calcite coating.

### BACKGROUND

Microfluidic systems, also referred to as “lab-on-a-chip” devices, can be used to mimic reservoir environments for fundamental enhanced oil recovery studies. Using microfluidic systems can provide a mode of directly testing wettability alteration using different fluids for enhanced oil recovery, for example. Many conventional materials used for microfluidic devices, such as silicon, are not suitable for studying carbonate reservoir systems. Calcite microfluidics can be used to study reservoir properties; however, calcite microfluidics are uncommon and techniques for their fabrication are under development.

Few methods exist for fabricating calcite microfluidics and such methods tend to be complex and time consuming to execute. Accordingly, there exists a need for facile methods for fabricating calcite microfluidic devices.

### SUMMARY

This summary is provided to introduce a selection of concepts that are further described below in the detailed description. This summary is not intended to identify key or essential features of the claimed subject matter, nor is it intended to be used as an aid in limiting the scope of the claimed subject matter.

In one aspect, embodiments disclosed herein relate to a method that includes 3d printing a polymer substrate comprising microfluidic channels and depositing calcite onto the polymer substrate then using atomic layer deposition to form a calcite microfluidic device.

In another aspect, embodiments disclosed herein relate to a 3d printed polymer substrate including microfluidic channels. The 3d printed polymer substrate has a calcite coating.

Other aspects and advantages of the claimed subject matter will be apparent from the following description and the appended claims.

### BRIEF DESCRIPTION OF DRAWINGS

FIG. 1 is a schematic of a method of making a calcite microfluidic device in accordance with one or more embodiments.

FIG. 2 is a schematic of a fused filament fabrication apparatus in accordance with one or more embodiments.

FIG. 3A is a top-down view of a microfluidic device in accordance with one or more embodiments.

FIG. 3B is a cross sectional view of a microfluidic device in accordance with one or more embodiments.

FIG. 4 is a cross sectional view of a microfluidic device in accordance with one or more embodiments.

### DETAILED DESCRIPTION

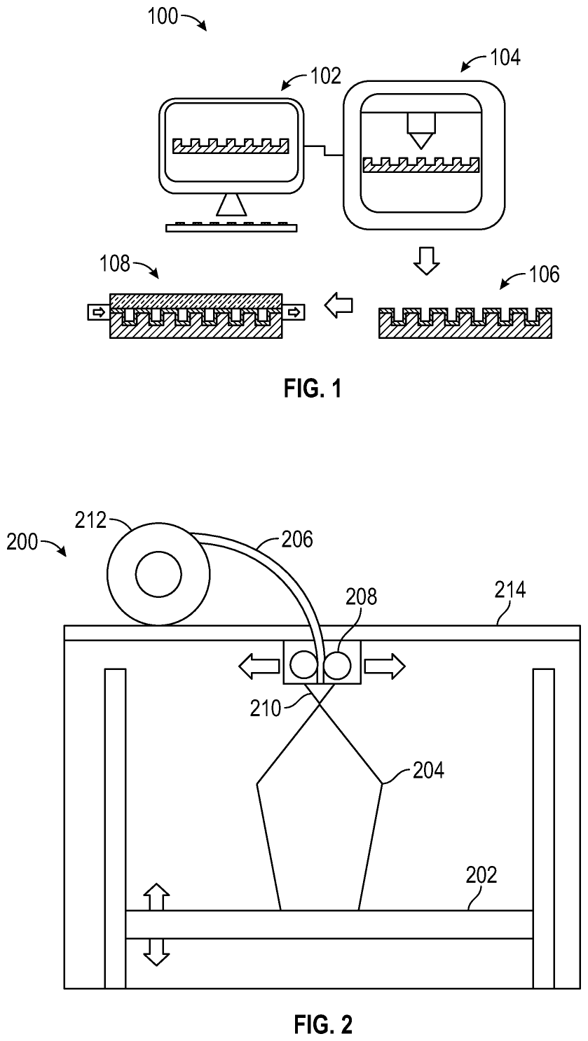

In one aspect, embodiments disclosed herein relate to a method of making a calcite (CaCO₃) microfluidic device. A schematic of a method 100 in accordance with one or more embodiments, as depicted in FIG. 1, includes designing a microfluidic device on a computer 102, printing a polymer substrate that includes microfluidic channels 104, and coating the polymer substrate with calcite using atomic layer deposition 106 to form a calcite microfluidic device. Once the microfluidic device has been fabricated, a glass window, an inlet and an outlet may be added 108 to fabricate a working microfluidic device. Methods in accordance with the present disclosure provide a facile method with high precision for making calcite microstructures suitable for fundamental studies of carbonate reservoirs.

As noted above, methods described herein include 3d printing a polymer substrate that includes microfluidic channels. As used herein, “3d printing” (also referred to as additive manufacturing) refers to a process that builds a three-dimensional (3d) object from a 3d model data, such as from a computer-aided design (CAD) model. 3d printing is generally a layer-by-layer process in which a 3d object is built one layer at a time, and each successive layer is added to the previously constructed layer(s). The 3d printing may be conducted using any suitable method, and in one or more particular embodiments, a fused filament fabrication (FFF) method may be used.

A schematic depiction of an FFF 3d printing apparatus 200 is shown in FIG. 2. The apparatus includes a substrate 202 upon which a 3d printed object 204 may be printed. The substrate 202 is configured to move in a vertical direction (indicated by the arrows) as the 3d printing process is conducted. The material to be printed is in the form of a filament 206 which is fed from a spool 212 through a roller 208 to a nozzle 210 through which the filament is extruded. The roller 208 is mounted on a horizontal stage 214 and may be configured to move in both horizontal and vertical directions, but is at least configured to move in horizontal directions (indicated by the arrows) to generate the pattern of the 3d printed object 204.

To 3d print an object using the FFF apparatus 200, a first layer of a polymer material (in the form of the filament 206) is printed directly onto the substrate 202. It is printed by extrusion through the nozzle 210, which is configured to heat the filament for printing. As the filament 206 is extruded through the heated nozzle, a continuous bead (also referred to as a “road”) of the polymer is deposited onto the substrate 202. The nozzle 210 is moved over the substrate in a predetermined geometry to form a first layer of the object 204. Once the first layer is completed, the substrate 202 is lowered away from the nozzle 210 and a second layer of the polymer is deposited onto the first layer. This process is repeated to build an object layer-by-layer until the object 204 is completed.

As understood by a person of skill in the art, a CAD model of an object to be printed with suitable dimensions may be generated prior to 3d printing the substrate. The CAD model may be designed using commercially available software, such as software provided with a commercially available 3d printer. Other readily available software such as AutoCAD, Fusion 360 or TinkerCAD may be used.

The 3d printer used to print devices in accordance with the present disclosure is not particularly limited, and may be any of a wide variety of commercially available 3d printers known by those skilled in the art. In one or more particular embodiments, Utilimaker 3d printers available from Dynamism (Chicago, IL, USA) may be used. In order to print the devices disclosed herein, the printer may have a resolution of up to about 20 microns.

Any polymer suitable for use in FFF printing may be used to print the devices disclosed herein. For example, the polymer filament may be selected from the group consisting of polylactic acid, acrylonitrile butadiene styrene, polyethylene terephthalate glycol, polyethylene terephtathalate, high-impact polystyrene, thermoplastic polyurethane, aliphatic polyamides, and combinations thereof. In particular embodiments, the polymer filament may be polylactic acid.

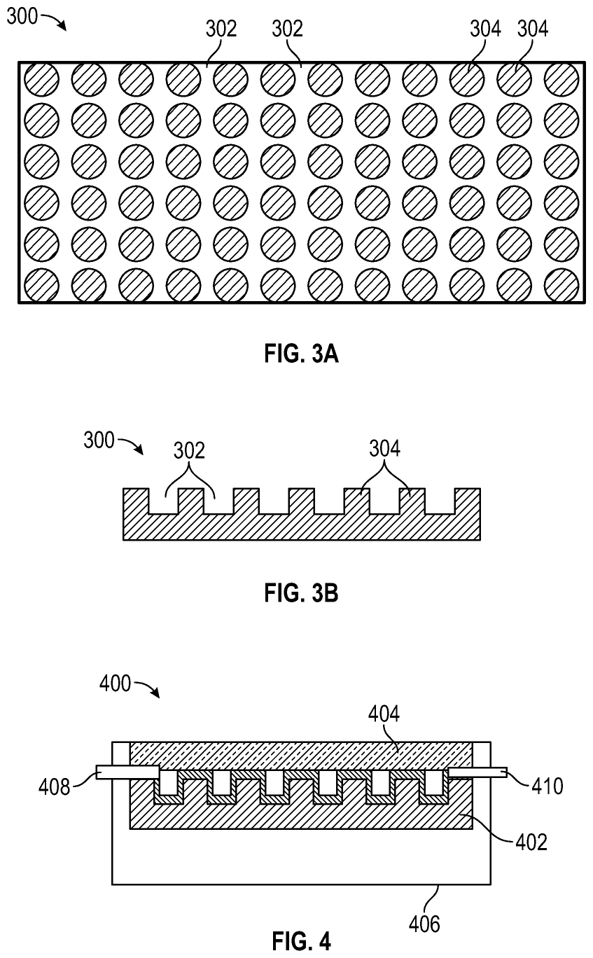

The 3d printed substrate may have a suitable structure with microscale dimensions for creating a calcite microfluidic device. A top-down view of such a substrate 300 is shown in FIG. 3A and a cross sectional view of shown in FIG. 3B. The substrate 300 includes channels 302 with raised portions 304 in between. The raised portions 304 are made of the previously described polymer and the channels 302 are empty space. While the channels are shown as circular in shape, they may be any suitable shape, such as square, rectangular and curved, provided the shape can readily be 3d printed. The channels depicted in FIGS. 3A and 3B are also regularly repeating and of similar sizes. However, the pattern may be varied as desired. The pores may be irregular in both shape and size and are only limited by the capabilities of the 3d printer. This structure, when built with microscale dimensions, forms the substrate, or template, for a microfluidic device.

The dimensions of the channels of the polymer substrate may be selected to mimic pores in a carbonate reservoir. For example, in one or more embodiments, the channels of the polymer substrate may have a width ranging from 10 to 500 microns. The width of the channels may have a lower limit of one of 10, 15, 20, 30, 50, 75, 100, 125, 150, 200 and 250 microns, and an upper limit of one of 100, 125, 150, 175, 200, 250, 300, 350, 400, 450 and 500 microns, where any lower limit may be paired with any mathematically compatible upper limit. The height of the channels may be from about 75 to 250 microns. For example, the height of the channels may have a lower limit of any of one 75, 80, 90, 100, 110, 125, 150, and 175 microns and an upper limit of any one of 125, 150, 175, 200, 225, and 250, where any lower limit may be paired with any mathematically compatible upper limit. The length of the channels may be selected based on the desired overall size of the microfluidic device. The channels of one or more embodiments may have a length ranging from 2.0 mm (millimeters) to 5.0 mm. The length of the channels may have a lower limit of one of 2.0, 2.25, 2.5, 2.75, 3.0, 3.25, and 3.5 mm and an upper limit of one of 3.75, 4.0, 4.25, 4.5, 4.75, and 5.0, where any lower limit may be paired with any mathematically compatible upper limit. As noted above, the sizes of the channels may be varied within the microfluidic device.

After 3d printing a polymer substrate, a calcite layer may be deposited on the polymer substrate using an atomic layer deposition (ALD) process. Atomic layer deposition is a thin film deposition technique in which a sequential gas-phase deposition processes is used to deposit layers of certain materials to build a thin film. ALD is a self-limiting process in which a gas is introduced into a deposition chamber, and a single atomic layer of the gaseous material deposits on a surface to form a single atomic layer. Once the single layer is formed, the gas is cleared from the deposition chamber and then another gas is introduced to form another layer on top of the previous layer. This process is repeated until the final material is formed.

In accordance with one or more embodiments, a calcite layer having a thickness of 50 to 150 nm (nanometers) may be formed using the following parameters. The temperature during the deposition may be between 250 and 325° C., and in particular embodiments, may be around 300° C. The gaseous precursors may be calcium 2,2,6,6-tetramethylheptan-3,5-dione (Ca(thd)₂), carbon dioxide (CO₂), and ozone (O₃). The calcite coating may be made, for example, by flowing a Ca(thd)2 precursor over the polymer substrate to form a calcium layer, purging with nitrogen gas, flowing a O₃ precursor over the polymer substrate to form an oxygen layer, purging with nitrogen gas, flowing a CO₂ precursor over the polymer substrate to form an oxygen layer, purging with nitrogen gas, and repeating the previously recited steps until the calcite layer is formed. A non-limiting example of a single deposition cycle to form calcium carbonate may include a 3 second pulse of Ca(thd)₂ followed by a 2 second nitrogen purge, a 3 second O₃ pulse followed by a 2 second nitrogen purge, and a 3 second CO₂ pulse followed by a 2 second nitrogen purge. The deposition cycle may be repeated a sufficient number of times to achieve a thickness of 50 to 150 nm. Specifically, the process may include from about 1,000 to about 3,000 cycles.

Once a suitable calcite coating has been formed, the uniformity of the calcite layer may be confirmed using scanning electron microscopy, and in some instances, focused ion beam scanning electron microscopy.

The 3d printed channels with a calcite coating may be packaged into a casing for final use as a microfluidic device. A cross sectional view of a final microfluidic device 400 in accordance with one or more embodiments is shown in FIG. 4. The microfluidic device includes calcite coated 3d printed channels 402 as described above. The device also includes a top portion comprising a window 404. The window may be transparent for visual inspection of the channels during use. The device has a bottom portion 406 configured to hold the device. The bottom portion 406 may be any type of casing to provide stability to the device and allow for the window 404 and fluid connections 408 410 to be properly connected. As shown in FIG. 4, the device includes an inlet 408 configured to allow a fluid to enter the device and an outlet 410 configured to allow the fluid to exit the device. The inlet 408 may be connected to a pump configured to introduce fluid at certain pressures and flow rates. The outlet 410 may be connected to a waste collection system for waste fluid after use. The inlet and outlet pictured in FIG. 4 are located on opposite sides of the device. However, their location is not particularly limited. They may be located on any sides of the device.

The device disclosed herein may be used to study fluid dynamics in calcite microchannels, which are configured to mimic pores in carbonate reservoirs. Carbonate reservoirs are routinely treated with acids to increase pore connectivity and ultimately enhance oil recovery in the reservoir. Acid achieves this effect by dissolving the carbonate rock. The devices disclosed herein may be used to visually observe the dissolution dynamics of various acid treatment mixtures on the deposited calcite, and thereby provide information about fluid flow dynamics. These observations can be used to quantify acid dissolution of the carbonate rock and to predict migration of brine through aquifers, such as calcite formations. Such observations may be made according to any technique known in the art. In particular, dissolution dynamics may be observed using an optical microscope equipped with a CCD camera.

Although only a few example embodiments have been described in detail above, those skilled in the art will readily appreciate that many modifications are possible in the example embodiments without materially departing from this invention. Accordingly, all such modifications are intended to be included within the scope of this disclosure as defined in the following claims. In the claims, means-plus-function clauses are intended to cover the structures described herein as performing the recited function and not only structural equivalents, but also equivalent structures. Thus, although a nail and a screw may not be structural equivalents in that a nail employs a cylindrical surface to secure wooden parts together, whereas a screw employs a helical surface, in the environment of fastening wooden parts, a nail and a screw may be equivalent structures. It is the express intention of the applicant not to invoke 35 U.S.C. § 112(f) for any limitations of any of the claims herein, except for those in which the claim expressly uses the words ‘means for’ together with an associated function.

What is claimed:

1. A method comprising:
3d printing a polymer substrate comprising microfluidic channels; and
using atomic layer deposition, depositing calcite onto the polymer substrate to form a calcite microfluidic device.

2. The method of claim 1, wherein the 3d printing is conducted using fused filament fabrication.

3. The method of claim 2, wherein the fused filament fabrication comprises:
feeding a polymer filament through a heated nozzle to deposit a first layer of the polymer onto a base;
depositing a second layer of the polymer onto the first layer; and
repeating the above steps until the polymer substrate is formed.

4. The method of claim 3, wherein the polymer filament is selected from the group consisting of polylactic acid, acrylonitrile butadiene styrene, polyethylene terephthalate glycol, polyethylene terephtathalate, high-impact polystyrene, thermoplastic polyurethane, aliphatic polyamides, and combinations thereof.

5. The method of claim 1, wherein the polymer of the polymer substrate is polylactic acid.

6. The method of claim 1, wherein the microfluidic channels have a width ranging from 10 to 500 microns.

7. The method of claim 1, wherein the microfluidic channels have a length ranging from 2 mm to 5 mm.

8. The method of claim 1, wherein a thickness of the calcite is from 50 to 150 nm.

9. The method of claim 1, wherein the using atomic layer deposition comprises:
flowing a Ca(thd)₂ precursor over the polymer substrate to form a calcium layer;
purging with nitrogen gas;
flowing a O₃ precursor over the polymer substrate to form an oxygen layer;
purging with nitrogen gas;
flowing a CO₂ precursor over the polymer substrate to form an carbon layer;
purging with nitrogen gas; and
repeating the above steps until the calcite layer is formed.

10. The method of claim 1, further comprising:
packaging the calcite microfluidic device in a casing, wherein the casing comprises a top portion comprising a window, a bottom portion configured to hold the device, an inlet configured to allow a fluid to enter the device, and an outlet configured to allow the fluid to exit the device.

11. A device comprising:
a 3d printed polymer substrate comprising microfluidic channels, wherein the 3d printed polymer substrate comprises a calcite coating.

12. The device of claim 11, wherein the polymer substrate is selected from the group consisting of polylactic acid, acrylonitrile butadiene styrene, polyethylene terephthalate glycol, polyethylene terephtathalate, high-impact polystyrene, thermoplastic polyurethane, aliphatic polyamides, and combinations thereof.

13. The device of claim 11, wherein the microfluidic channels have a width ranging from 10 to 500 microns.

14. The device of claim 11, wherein the microfluidic channels have a length ranging from 2 mm to 5 mm.

15. The device of claim 11, wherein a thickness of the calcite coating is from 50 to 150 nm.

16. The device of claim 11, further comprising:
a top portion comprising a window;
a bottom portion configured to hold the device;
an inlet configured to allow a fluid to enter the device; and
an outlet configured to allow the fluid to exit the device.
